(19) United States
(12) Patent Application Publication
(10) Pub. No.: US 2023/0178342 A1
(43) Pub. Date: Jun. 8, 2023

(54) MID-CHAMBER FLOW OPTIMIZER

(71) Applicant: Lam Research Corporation, Fremont, CA (US)

(72) Inventors: Craig Rosslee, San Jose, CA (US); Ambarish Chhatre, Danville, CA (US); Ming-Te Lin, Fremont, CA (US); Dan Marohl, San Jose, CA (US)

(21) Appl. No.: 17/924,354

(22) PCT Filed: Apr. 30, 2021
(86) PCT No.: PCT/US21/30150

§ 371 Date: Nov. 9, 2022

Related U.S. Application Data
(60) Provisional application No. 63/033,013, filed on Jun. 1, 2020.

(51) Int. Cl. H01J 37/32

(52) U.S. Cl. CPC H01J 37/32449; H01J 37/32733; H01J 2237/20235; H01J 2237/334

(57) ABSTRACT

A flow optimizer is disclosed for use in plasma chamber. The flow optimizer includes a ring that is disposed between a wafer support and a dielectric window defined in the plasma chamber. The ring of the flow optimizer is configured to be positioned between the wafer support and the dielectric window so that an outer edge of the ring is adjacent to side walls of the plasma chamber and an opening of the ring is substantially aligned with a diameter of the wafer support.

### FIELD

The present embodiments relate to systems and methods for improving etch rate of an etcher that is used to generate electronic devices.

### BACKGROUND

A wafer processing tool includes one or more process chambers that are used to perform various fabrication operations in order to define electronic devices on a substrate. One of the emerging fields in the fabrication of electronic devices is the field of micro-electromechanical systems (MEMS). MEMS is a process technology that uses integrated circuit processing techniques to create tiny integrated devices that include mechanical and electronic components. MEMS devices, such as sensors, actuators, etc., are widely used in various fields. MEMS devices are fabricated using micromachining technology wherein the thickness of a silicon substrate (i.e., wafer) is used for building micro-mechanical structures. Layers are deposited on the surface of the substrate and micro-mechanical structures are built using the deposited layers. The structures defined on the substrate can be combined with integrated circuits formed in the substrate to generate three-dimensional MEMS electronic devices.

Different process modules of the wafer processing tool are used for performing different operations to define the electronic devices. For example, a first process chamber may be used to deposit layers of structural materials over a surface of the substrate, a second process chamber may be used to perform selective etching to remove layers of material from the surface of the substrate, and so on. The etching may be done to define trenches, vias, etc., on the substrate surface.

A high throughput of MEMS devices can be achieved by etching large amounts of silicon quickly. One way of providing high throughput is by increasing the amount of reactant species applied to the substrate surface. The amount of reactant species may be increased by increasing power (e.g., radio frequency power) applied to the process gas in the plasma region and/or by increasing the process gas flow.

The aforementioned ways of increasing the amount of reactant species in the plasma region come with its own tradeoffs. Some of the tradeoffs include degradation of the profile of devices defined on the substrate surface, reduced etch uniformity, and increased costs due to higher energy and chemical consumption.

It is in this context that embodiments described in the present disclosure arise.

### SUMMARY

The various implementations describe apparatus, systems and methods for increasing amount of reactant species applied to a surface of a substrate (alternately referred to herein as “wafer”). The amount of reactant species applied to the wafer is increased by introducing a ‘donut’ or ring-shaped plate between a plasma region and a wafer support defined in a plasma chamber used for processing the wafer. Process gas is supplied to the plasma region from a process gas source and radio frequency (RF) power is supplied to generate reactant species. Vacuum created by a pump disposed in a bottom portion of the plasma chamber causes the reactant species to flow down toward the pump. The donut shaped plate disposed in the process chamber is positioned such that an opening of the donut shaped plate is aligned over the wafer support in the plasma chamber. As the reactant species flows toward the bottom of the plasma chamber, the opening in the donut shaped plate forces a fraction of the reactant species of the plasma to pass close to the top surface of the wafer, so that the reactant species can react with the wafer. The donut shaped plate optimizes the flow of the reactant species closer to the surface of the wafer, and henceforth is also referred to herein as a “flow optimizer”.

The flow optimizer funnels the existing reactant species away from the side walls of the plasma chamber toward the wafer surface, thereby increasing the amount of reactant species applied to the wafer surface. This increase in the amount of the reactant species near the wafer surface is achieved without having to increase the flow of the process gas or the RF power used to generate plasma. As a result, there is no need to deal with any tradeoffs, such as degradation in structural profiles, reduction in etch uniformity, higher energy and chemical consumption costs, etc.

In one implementation, a flow optimizer for use in a plasma chamber is disclosed. The plasma chamber includes sidewalls, a wafer support and a dielectric window disposed opposite to the wafer support to define a plasma region therebetween. A gas inlet is provided through the dielectric window to direct gas to the plasma region. The flow optimizer includes a ring having an annular surface with an inner edge that extends an inner diameter and an outer edge that extends to an outer diameter. The ring is disposed so that the outer edge is adjacent to the side walls of the plasma chamber and the inner diameter defines an opening. The flow optimizer is configured to be positioned between the wafer support and the dielectric window so that an opening of the ring substantially aligns with a diameter of the wafer support.

In another implementation, a plasma chamber is disclosed. The plasma chamber includes side walls, a wafer support and a dielectric window disposed opposite to the wafer support to define a plasma region located therebetween. A gas inlet is defined through the dielectric window to direct gas flow to the plasma region. The plasma chamber includes a flow optimizer. The flow optimizer includes a ring with an annular surface defined by an inner edge that extends to an inner diameter and an outer edge that extends to an outer diameter. The ring is disposed such that the outer edge of the ring is adjacent to the side walls of the plasma chamber and the inner diameter defines an opening. The ring is configured to be positioned between the wafer support and the dielectric window so that the opening of the ring is aligned with a diameter of the wafer support. The flow optimizer is supported on a plurality of support pegs defined on an inner side of the side walls of the plasma chamber. The plurality of support pegs are disposed above the wafer support so that a separation distance exists between the wafer support and the ring of the flow optimizer.

In yet another implementation, a flow optimizer for use in a plasma chamber is disclosed. The plasma chamber includes side walls, a wafer support and a dielectric window disposed opposite to the wafer support to define a plasma region therebetween. A gas inlet is provided through the dielectric window for directing gas to the plasma region. The flow optimizer includes an inner disk defined in a center and aligned with a diameter of the wafer support. An outer edge of the inner disk extends to a first diameter. The flow optimizer also includes an outer ring with an annular surface defined by an inner edge that extends a second diameter and an outer edge that extends to a third diameter, wherein the third diameter extends to side walls of the plasma chamber. The inner edge of the outer ring is separated from the outer edge of the inner disk by a gap that exposes a portion of a wafer received on the wafer support. A plurality of connector pins is configured to connect the outer edge of the inner disk to the inner edge of the outer ring. The flow optimizer is configured to be positioned between the wafer support and the dielectric window.

Advantages of providing the flow optimizer in the plasma processing systems include an ability to increase amount of reactant species directed over a surface of a wafer without having to increase the amount of process gas supplied to the plasma chamber. The increase in the amount of reactant species directed over the wafer surface results in an improvement in the etch rate on the wafer surface, and such improvement come for ‘free’ as the improvement is from the reactant species that already exists in the plasma chamber. By more efficiently funneling the existing reactant species available in the plasma chamber, the tradeoffs resulting from generation of additional reactant species can be avoided. The generation of additional reactant species may be achieved by increasing radio frequency (RF) power applied to the process gas in the plasma region and/or increasing the flow of the process gas into the processing chamber. Increasing RF power or flow of process gas come with tradeoffs. The tradeoffs (e.g., degraded profiles, worse etch uniformity, etc.) resulting from such changes can be avoided by using the flow optimizer to efficiently increasing an amount of the existing reactant species generated in the processing chamber toward the wafer surface so that the etch rate on the wafer surface can improve.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1A is a simple block diagram of a plasma chamber that shows flow of gas, in accordance with one implementation.

FIG. 1B illustrates a simple block diagram of a plasma chamber with a flow optimizer disposed midway to improve amount of reactant species over the surface of the wafer, in accordance with one implementation.

FIG. 2 illustrates a side, cross-sectional view of a plasma chamber in which a mid chamber flow optimizer is disposed, in accordance with one implementation.

FIG. 3A illustrates a cross-sectional view of a support peg defined on an inner side of the side wall of the plasma chamber to support the mid chamber flow optimizer, in accordance with one implementation.

FIG. 3B illustrates a cross-sectional view of a spacer defined between the mid chamber flow optimizer and a bevel shadow ring, in accordance with an alternate implementation.

FIG. 4A illustrates an overhead view of a mid chamber flow optimizer that is disposed over a wafer support, in accordance with one implementation.

FIG. 4B illustrates an overhead view of a mid chamber flow optimizer with a plurality of stress relief cuts defined on the surface to avoid thermally driven failures, in accordance with one implementation.

FIG. 5A illustrates a simplified overhead view of different components of a mid chamber flow optimizer, in accordance with one implementation.

FIG. 5B illustrates an alternate implementation of the mid chamber flow optimizer with a plurality of stress relief cuts defined on the surface.

FIG. 5C illustrates a second alternate implementation of the mid chamber flow optimizer with a plurality of rings.

FIG. 6A illustrates a simplified block diagram of a mid chamber flow optimizer with plasma confining liner, in accordance with one implementation.

FIG. 6B illustrates a simplified block diagram of an alternate design of a mid chamber flow optimizer, in accordance with one implementation.

FIG. 6C illustrates a simplified block diagram of a second alternate design of a mid chamber flow optimizer, in accordance with one implementation.

### DETAILED DESCRIPTION

The following embodiments describe systems and methods for improving an amount of reactant species applied to a surface of a wafer within a plasma chamber. It will be apparent that the present embodiments may be practiced without some or all of these specific details. In other instances, well known operations have not been described in detail in order not to unnecessarily obscure the present embodiments.

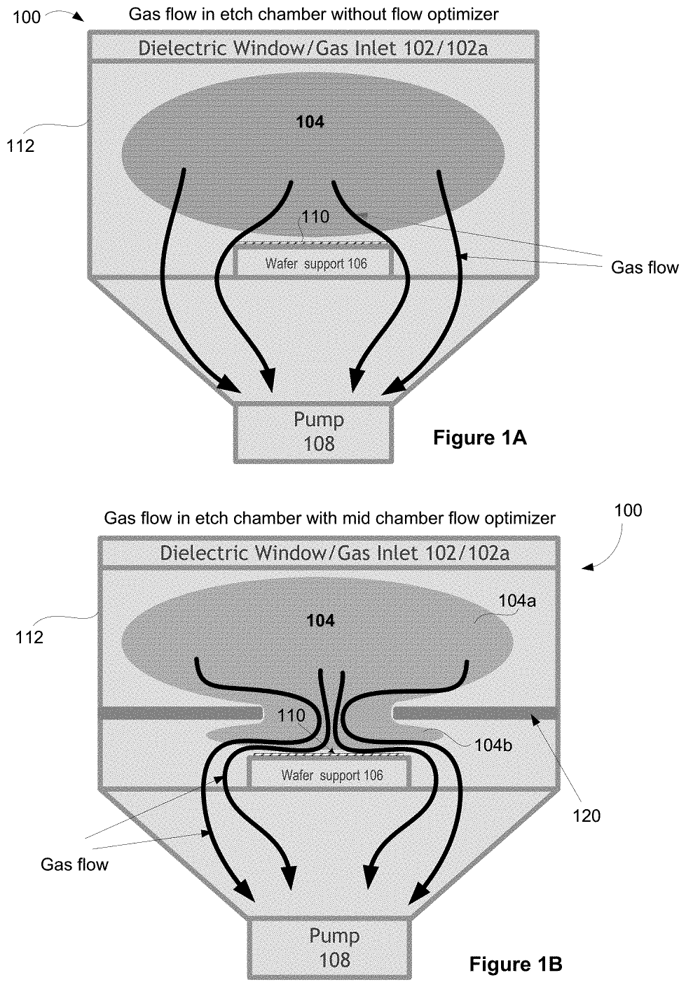

FIG. 1A is a simplified block diagram of an embodiment of a plasma processing system used to improve etch rate on a surface of a wafer during an etching operation, in one implementation. The etch rate can be improved by increasing the amount of reactant species applied to the surface of the wafer. In one implementation, the plasma processing system includes a transformer coupled plasma (TCP) etch chamber 100 (simply referred to herein onward as “chamber” 100). The type of chamber 100 is not restricted to TCP chamber but could also be an Capacitively Coupled Plasma (CCP) etch chamber, for example. The chamber 100 is defined by side walls 112 and surround a wafer support 106a defined in a lower portion 106 of the chamber 100. The wafer support 106a is configured to receive a wafer 110 for processing. The wafer support 106a may be in the form of an electrostatic chuck (ESC) or a pedestal that is coupled to a radio frequency (bias) power (not shown) through a corresponding match network (not shown). A dielectric window 102 is defined in an upper portion 105 of the chamber 100 and is oriented opposite to the wafer support 106a to define a plasma region 104 therebetween. One or more gas inlets 102a may be provided through the dielectric window 102 to introduce process gas from a process gas source (not shown) into the plasma region 104. One or more TCP coils (e.g., inner, outer coils—not shown) may be disposed above the dielectric window 102 and be used to provide power to the plasma region 104 to generate plasma. Consequently, the TCP coils may be coupled to one or more radio frequency (RF) power source (not shown) through a corresponding match network (not shown). Each RF power source is configured to generate RF power of particular frequency.

The dielectric window 102 may be defined from a ceramic material. The dielectric window 102 is not restricted to the ceramic material but other dielectric materials are also possible, so long as they are capable of withstanding the conditions of the chamber 100. Typically, chamber 100 operates at elevated temperatures and the operating temperatures will depend on the etching process operation conducted therein and a specific recipe used within the chamber 100.

The chamber 100 will also operate at vacuum conditions to remove the reactant species of the plasma generated within the chamber 100. A pump 108 is defined below the wafer support 106a to enable vacuum control and removal of gaseous byproducts (i.e., reactant species) from the chamber 100 during operational plasma processing. The vacuum conditions at which the pump 108 operates the chamber 100 may be in the range of between about 1 m Torr (mT) and about 1 Torr, although other ranges may also be envisioned. Although not shown, chamber 100 is typically coupled to facilities when installed in a clean room, or in a fabrication facility. Facilities include plumbing that provide processing gases, vacuum, temperature control, and environmental particle control. Additionally, when the chamber 100 is part of a cluster tool, the chamber 100 may be coupled to a transfer chamber (not shown) that will enable robots to transfer wafers into and out of the chamber 100 using typical automation.

The power provided through the TCP coils in the dielectric window 102 is applied to the process gas to generate plasma within the plasma region 104 defined between the dielectric window 102 and the wafer support 106a. Vacuum applied by the pump 108 causes the reactant species of the plasma to flow from the plasma region 104 toward the pump 108 and removed from the chamber 100 via one or more slots defined proximate to a bottom surface of the wafer support 106a disposed in the chamber 100. In the implementation illustrated in FIG. 1A, the reactant species follows the gas flow path identified by the dark arrows from the plasma region 104 toward the pump 108. In this implementation, some portion of the reactant species flows toward the surface of the wafer while the remaining portion of the reactant species flows away from the surface of the wafer 110 and, in many cases, flows close to the side walls 112 of the chamber 100. Due to the amount of the reactant species being applied to the wafer surface, in this implementation, the etch rate on the wafer surface may be sub-optimal.

FIG. 1B illustrates an implementation in which a mid-chamber flow optimizer (or simply referred to herein onward as “flow optimizer”) 120 is disposed in the chamber 100 to improve the etch rate on the surface of the wafer. The flow optimizer 120 is positioned between the wafer support 106a and the dielectric window 102, with a separation distance defined between the wafer support 106a and the flow optimizer 120. The flow optimizer 120 is defined by a ring with an annular surface having an inner edge and an outer edge. The inner edge of the ring extends an inner diameter to define an opening. The outer edge of the ring extends to an outer diameter. The ring is configured so that the outer diameter of the ring extends to side walls 112 of the chamber 100. This results in the outer edge of the ring being disposed adjacent to the side walls 112 of the chamber 100. In this implementation, the outer diameter of the ring is substantially equal to an inner diameter of the side walls 112 of the chamber 100. The flow optimizer 120 is disposed in the chamber 100 so that the opening of the ring is substantially aligned with a diameter of the wafer support 106a. In some implementations, the diameter of the opening (i.e., diameter of the inner edge) of the ring is greater than, equal to, or less than the diameter of the wafer support 106a. The flow optimizer 120, in one implementation, is made of ceramic. In other implementations, the flow optimizer 120 can be made of any other material that can withstand the operational conditions of the plasma chamber and exhibit similar thermal properties as the ceramic material. The flow optimizer 120 dissects the plasma region 104 defined between the wafer support 106a and the dielectric window 102 into an upper plasma region 104a and a lower plasma region 104b. The upper plasma region 104a is connected to the lower plasma region 104b at the opening of the ring of the flow optimizer 120 so that the reactant species of the lower plasma region 104b have sufficient resident time over the surface of the wafer for the reactant species to react with the wafer surface.

In some implementations, the flow optimizer 120 may be supported on one or more support pegs (not shown) that are attached to the side walls 112 of the chamber 100. In alternate implementations, the flow optimizer 120 may be supported on one or more spacers (not shown) disposed over a bevel shadow ring (not shown) when the bevel shadow ring is disposed in the chamber 100. The opening of the ring defined over the wafer support 106a direct the reactant species from the plasma region to flow away from the side walls 112 of the chamber 100 and toward the surface of the wafer 110, as shown by the dark arrows in FIG. 1B. Further, the annular surface of the ring of the flow optimizer 120 dissects the plasma region 104 into an upper plasma region 104a and a lower plasma region 104b with the upper plasma region 104a connected to the lower plasma region 104b at the opening of the ring of the flow optimizer 120. The flow of the reactant species from the upper plasma region 104a to the lower plasma region 104b is restricted by the annular surface of the ring, thereby forcing the reactant species to flow toward the opening and toward the wafer 110 received on the wafer support 106a, as shown by the black arrows in FIG. 1B. The size of the opening may be defined based on specific portions of the surface of the wafer 110 that needs to be targeted and the amount of reactant species that needs to be funneled toward the specific portions of the surface of the wafer 110. In some implementations, a diameter of an inner edge of the ring may be defined so that a portion of the ring overhangs over a portion of the wafer edge of the wafer 110 received on the wafer support 106a. In this implementation, the diameter of the inner edge of the ring is less than the outer diameter of the wafer 110. The ring of the flow optimizer 120 is used to funnel the reactant species of the plasma that is already present in the chamber toward the wafer surface, thereby increasing the amount of the reactant species on the wafer surface. The increase in the reactant species at the wafer surface is achieved without increasing RF power or amount of process gas in the chamber 100. This increase in the reactant species on the wafer surface results in improved etch rate.

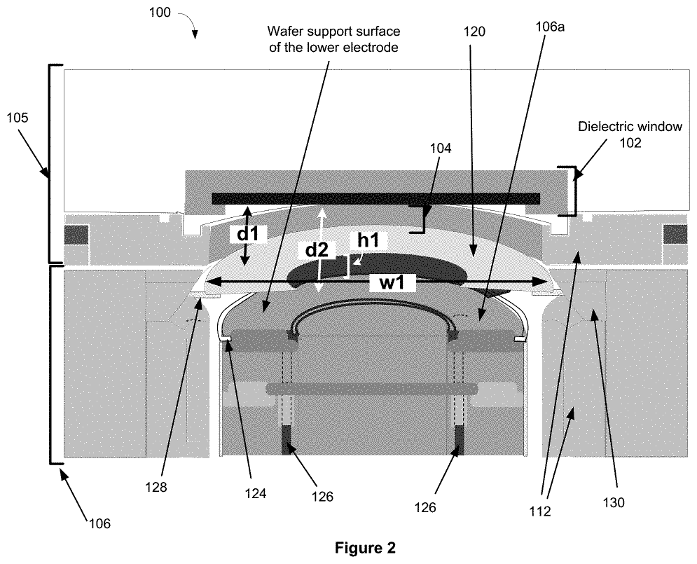

FIG. 2 illustrates a simplified cross-sectional view of a chamber 100 in which a flow optimizer 120 is disposed, in one implementation. The cross-sectional view identifies different components of the chamber 100. Broadly speaking, the chamber 100 includes a dielectric window 102 disposed in an upper portion 105 of the chamber 100. The dielectric window 102 is coupled to a gas source that supplies process gas through one or more gas inlets 102a to a plasma region 104 defined in the chamber 100, and to a power supply through one or more TCP coils that provide power to generate plasma, for example. The chamber 100 also includes a wafer support 106a defined in a lower portion 106 of the chamber 100. In one implementation, the wafer support 106a is used to support a carrier ring 124 with a wafer 110 received thereon. In another implementation, the wafer support 106a is used to directly support a wafer 110 received thereon. A pump 108 is provided in the lower portion 106 of the chamber 100 to provide vacuum to the chamber 100 in order to remove reactant species from the chamber 100. The dielectric window 102 is oriented opposite to the wafer support 106a to define the plasma region 104 therebetween. Side walls 112 of the chamber 100 define the boundary of the plasma region 104. The side walls 112 of the upper and the lower portions (105, 106) of the chamber 100 mate to seal the chamber 100, during processing of the wafer 110. In the implementation illustrated in FIG. 2, a top part of the side walls 112 in the lower portion 106 of the chamber 100 is contoured, so as to provide sufficient gap for the reactant species of the plasma to escape the plasma region 104 and flow toward the pump 108 disposed below the wafer support 106a. A portion of the contoured part in the lower portion 106 of the side wall 112 is shown in FIG. 2 as chamber wedge 130. The chamber wedge 130 is oriented to align with a gap defined between a flow optimizer 120 and the wafer support 106a.

In some implementations, the flow optimizer 120 is supported on support pegs 128 defined in the side walls 112 of the chamber 100. In one implementation, the support pegs 128 are defined to extend from the chamber wedge 130. The flow optimizer 120 is defined to sit at a height ‘h1’ above the wafer support 106a on which the wafer 110 is received. In alternate implementations where a bevel shadow ring (not shown) is used, the bevel shadow ring is disposed above a surface of the wafer support 106a and the flow optimizer is defined to be received above the bevel shadow ring such that a gap exists between the bevel shadow ring and the flow optimizer 120. Sufficient gap is defined to allow the flow of the reactant species from the plasma region 104 toward the wafer surface and the reactant species have sufficient resident time over the wafer surface for the reactant species to react with the wafer surface. The bevel shadow ring may be used when the bevel edge of the wafer 110 has to be covered to prevent etching of the bevel edge.

In some implementations, the height ‘h1’ at which the flow optimizer 120 is disposed above the wafer support 106a, such as an electrostatic chuck, may be defined to be about 1″ above the wafer 110 received on the wafer support 106a defined in the lower portion 106 of the chamber 100. The flow optimizer 120 is disposed above the wafer support 106a so that an opening of the ring substantially aligns with the diameter of the wafer support 106a. The annular surface of the ring extends to the side walls of the chamber 100. Consequently, the outer diameter of the ring ‘w1’ is substantially equal to the inner diameter of the side walls of the chamber 100. The size of the opening, the width of the annular surface, and the height h1 at which the flow optimizer 120 is disposed above the wafer support 106a are defined to funnel an optimal amount of reactant species generated in the chamber 100 toward the wafer surface. In some implementation, the diameter of the opening of the flow optimizer 120 is defined to be equal to or greater than the diameter of the wafer support 106a. In alternate implementations, the diameter of the opening of the flow optimizer 120 is less than the diameter of the wafer support 106a. In some implementations, the diameter of the opening of the flow optimizer 120 is equal to or greater than the diameter of the wafer 110 received on the wafer support 106a. In alternate implementations, the diameter of the opening of the flow optimizer 120 is less than the diameter of the wafer 110. The opening in the flow optimizer 120 is sized to control the portion of the wafer 110 that is to be exposed and the amount of reactant species that is to be funneled to the wafer surface. For example, when the center region of the wafer 110 needs to be exposed to the reactant species, the opening and the annular surface of the flow optimizer 120 are defined to expose the center region of the wafer 110. In this example, the remaining portions of the wafer 110 received on the wafer support 106a is covered by the annular surface of the ring of the flow optimizer 120.

In one implementation, the support pegs 128 defined in the side walls 112 of the chamber 100 may extend inward for a length so as to provide reliable support for the flow optimizer 120. In alternate implementations, spacers (not shown) may be disposed on the wafer support 106a to support the annular surface of the flow optimizer 120. The flow optimizer 120 may be made of a material that has a low coefficient of thermal expansion (CTE) or a material that has high thermal conductivity.

In the implementations where a carrier ring 124 is received on the wafer support 106a, the carrier ring 124 may include a recess for supporting the wafer 110. In one implementation, the wafer support 106a on which the carrier ring 124 is received may include a recess defined at an outer edge into which an extension of the carrier ring 124 is received. In such implementation, the profile of the recess defined in the wafer support 106a matches a contour of the extension defined in the underside surface of the carrier ring 124. Alternately, the top surface of the wafer support 106a may be planar and the underside surface of the carrier ring 124 received on the top surface of the wafer support 106a is also planar.

In the implementation where spacers (not shown) are defined on the wafer support 106a to support the flow optimizer 120, the spacers extend for a height so as to define a gap between the flow optimizer 120 and the wafer support 106a. The size of the gap between the wafer support 106a and the flow optimizer 120 is to allow the reactant species of the plasma to flow toward the wafer surface through the opening in the flow optimizer 120 and outward from the wafer surface toward the gap between the side walls 112 of the chamber 100 and the outer edge of the wafer support 106a. When present, the spacers are defined uniformly along the wafer support 106a so as to align with outer edge of the annular surface of the flow optimizer 120.

In one implementation, the flow optimizer 120 is disposed below the dielectric window 102 at a distance ‘d1’. In some implementations, the distance d1 is defined to be between about 1.5″ and about 2.5″. Similarly, the carrier ring 124, when present, is disposed below the dielectric window 102 at a distance ‘d2’. Alternately, when the bevel shadow ring is present, the bevel shadow ring is disposed below the dielectric window 102 at a distance ‘d2’. In some implementations, the distance d2 is defined to be between about 2.5″ and 3.5″. In some implementations, the distance h1 between the flow optimizer 120 and the wafer support 106a is defined to be about 1″. The outer diameter ‘w1’ of the ring of the flow optimizer 120 is defined to be substantially equal to the inner diameter of the side walls 112 of the chamber 100. In one implementation, if the inner diameter of the side walls 112 of the chamber 100 is about 14″, the width w1 (i.e., outer diameter of the annular surface of the ring) is defined to be between about 13.5″ and about 13.99″. The difference in the width of the side walls 112 of the chamber 100 and the outer edge of the flow optimizer 120 is to provide sufficient tolerance for the annular ring expansion. It should be noted that the aforementioned dimensions are provided as examples and should not be considered limiting. The distances between the flow optimizer 120 and the dielectric window 102, between the wafer support 106a and the dielectric window 102, between the flow optimizer 120 and the wafer support 106a and the outer diameter of the flow optimizer 120 may depend on the interior profile of the chamber 100.

In one implementation, the wafer support 106a includes a lift pin mechanism that is connected to a plurality of lift pins 126. The lift pins 126 are distributed uniformly along a circumference of the wafer support 106a and are received in corresponding housing defined in the wafer support 106a. The lift pin mechanism is coupled to a controller (not shown). The flow optimizer 120, in this implementation, is supported on a plurality of support pegs 128 defined on the side walls 112 of the chamber 100, and a carrier ring 124 is used to support the wafer 110. Control signals from the controller are used to operate the lift pin mechanism to enable the lift pins 126 to be moved to a raised position, when the lift pin mechanism is engaged, or a rested position, when the lift pin mechanism is disengaged. When the lift pins 126 are engaged, the lift pins 126 extend out of the corresponding housing in the wafer support 106a and lift the carrier ring 124 with the wafer 110 received thereon upward from the wafer support 106a. For example, the lift pin mechanism may be engaged when a wafer 110 needs to be moved into or out of the chamber 100. A robot of a vacuum transfer module or any other module to which the chamber 100 is coupled within a substrate processing system may be used to move the carrier ring 124. When the wafer 110 has to be moved out of the chamber 100, the lift pin mechanism is engaged to move the carrier ring 124 to a height so as to allow an end-effector on an arm of the robot inhindered access to the carrier ring 124. The end-effector supports the carrier ring 124 with the wafer 110 and moves the carrier ring 124 out of the chamber 100. The height to which the carrier ring 124 is moved upward within the chamber 100, in one implementation, is less than the height at which the flow optimizer 120 is disposed on the support pegs 128. The side walls 112 of chamber 100 and the chamber wedge 130, and the height at which the flow optimizer 120 is disposed are designed to ensure that there is sufficient space for moving the carrier ring 124 vertically upward inside the chamber 100, when lifted by the lift pins. The height at which the flow optimizer 120 is disposed and the height to which the carrier ring 124 can be moved by the lift pins 126 depends on the amount of space available in the chamber 100.

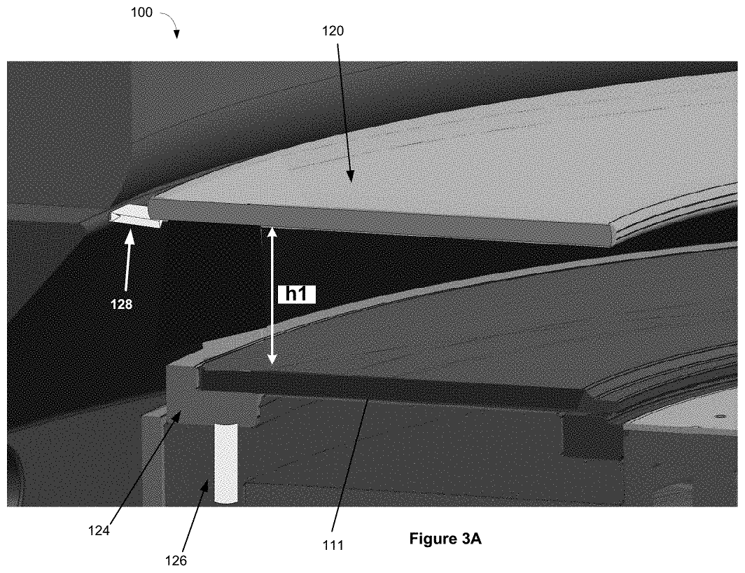

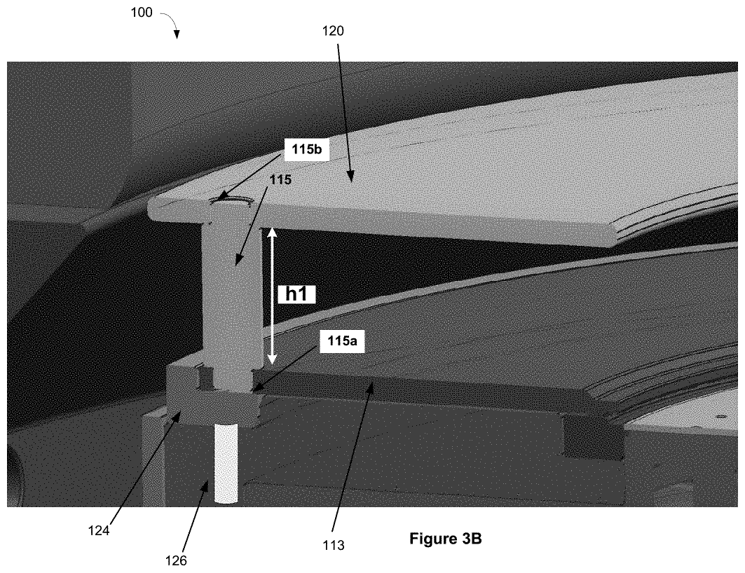

FIG. 3A illustrates an expanded, cross-sectional view of a portion of the chamber 100 where a flow optimizer 120 is disposed, in one implementation. The flow optimizer 120 is supported on a support peg 128 and is disposed at a height ‘h1’ above a wafer support surface 111 of a carrier ring 124. The carrier ring 124 is used to receive and support a wafer 110 during processing. The height h1 is defined so as to provide sufficient gap for the reactant species of the plasma to escape toward the pump 108 disposed below the wafer support surface 111. A corresponding lift pin 126 is defined in the wafer support 106a to align with the carrier ring 124 so as to support and move the carrier ring 124 with the wafer 110 received thereon upward toward the flow optimizer 120. The lift pins 126 are disposed in the wafer support 106a so that it aligns with the carrier ring 124. In one implementation, the number of support pegs 128 distributed along the side walls 112 of the chamber 100 is to ensure reliable support is provided to the flow optimizer 120 to withstand the process conditions in the chamber 100.

FIG. 3B illustrates an expanded, cross-sectional view of a portion of the chamber 100 where a flow optimizer 120 and a bevel shadow ring 113 are disposed, in an alternate implementation. In this implementation, the bevel shadow ring 113 is defined to sit just above the wafer support 106a (not shown) on which the wafer 110 (not shown) is received. The bevel shadow ring is used to cover a bevel edge of the wafer 110 so that the bevel edge of the wafer 110 does not get etched. In some implementations, the bevel shadow ring 113 may be disposed at a height that is between about 0.1 mm and about 1 mm above the wafer 110 received on the wafer support 106a, such as an electrostatic chuck, defined in the lower portion 106 of the chamber 100. The amount of bevel edge of the wafer covered by the bevel shadow ring 113 may depend on the amount of bevel edge defined on the wafer and the amount of bevel edge that needs to be protected from being etched. In some cases, the bevel edge of the wafer may extend between about 0 mm and about 5 mm.

When the bevel shadow ring is disposed in the chamber 100, the flow optimizer 120 is disposed at a height ‘h1’ above the bevel shadow ring 113. In one implementation, the bevel shadow ring 113 is disposed on a carrier ring 124 received on the wafer support 106a, such that a gap exists between the bevel shadow ring 113 and the flow optimizer 120. The carrier ring 124, in this implementation, is disposed over a wafer support 106a on which a wafer 110 is received for processing, such that the bevel shadow ring 113 is offset from the surface of the wafer 110 received on the wafer support 106a by a separation distance. The separation distance between the bevel shadow ring 113 and the wafer 110 received on the wafer support 106a may be between about 0.1 mm and 1 mm. The gap defined between the bevel shadow ring 113 and the flow optimizer 120 is defined to be sufficient to allow the reactant species to flow from the plasma region 104 toward the wafer surface and have sufficient resident time over the wafer surface to react with the wafer surface.

The flow optimizer 120 is disposed above the wafer support 106a so that an opening of the ring substantially aligns with the diameter of the wafer support 106a. The annular surface of the ring of the flow optimizer 120 extends to the side walls of the chamber 100. Consequently, the outer diameter of the ring is substantially equal to the inner diameter of the sidewalls of the chamber 100. The size of the opening, the width of the annular surface, and the height at which the flow optimizer 120 is disposed above the wafer support 106a are defined to funnel an optimal amount of reactant species generated in the chamber 100 toward the wafer surface. In some implementation, the diameter of the opening of the flow optimizer 120 is defined to be equal to or greater than the diameter of the wafer support 106a. In alternate implementations, the diameter of the opening of the flow optimizer 120 is less than the diameter of the wafer support 106a. In another implementation, the diameter of the opening of the flow optimizer 120 is less than the diameter of the wafer 110 received on the wafer support 106a. Alternately, the diameter of the opening of the flow optimizer 120 is greater than or equal to the diameter of the wafer 110 received on the wafer support 106a. The opening is sized to control the portion of the wafer 110 that is to be exposed and the amount of reactant species that is to be funneled to the wafer surface. For example, when the center region of the wafer 110 needs to be exposed to the reactant species, the opening and the annular surface of the flow optimizer 120 may be defined to expose the center region of the wafer 110. In this example, the diameter of the opening of the flow optimizer 120 may be less than the diameter of the wafer 110 so that remaining portions of the wafer 110 received on the wafer support 106a is covered by the annular surface of the ring of the flow optimizer 120. The bevel shadow ring 113 may be made of similar material as the flow optimizer 120. In one implementation, the bevel shadow ring 113 is made of a material that has a low coefficient of thermal expansion (CTE) or a material that has high thermal conductivity.

In one implementation where the bevel shadow ring 113 is received on a carrier ring 124, the wafer support 106a may include a recess defined at an outer edge into which the carrier ring 124 with the bevel shadow ring 113 is received. The contour of a bottom surface of the carrier ring 124 is designed to match the contour of the wafer support 106a, which includes the recess at the outer edge. Alternately, the top surface of the wafer support 106a may be planar and the carrier ring 124 with the bevel shadow ring 113 may be received on the top surface of the wafer support 106a. In some implementations, the bevel shadow ring 113 is defined such that it covers a portion of an edge of the wafer 110 received on the wafer support 106a.

In one implementation, a plurality of spacers 115 are defined between the bevel shadow ring 113 and the flow optimizer 120. The plurality of spacers 115 extends for a height to define a gap between the flow optimizer 120 and the bevel shadow ring 113. The gap between the bevel shadow ring 113 and the flow optimizer 120 is defined to allow the reactant species of the plasma to first flow toward the wafer surface and then outward toward the pump 108 via the gap defined between the side walls 112 of the chamber 100 and the wafer support 106a. The plurality of spacers 115 is defined uniformly along the bevel shadow ring 113 so as to align with the annular surface of the flow optimizer 120. In one implementation, there are 3 spacers 115 that are distributed uniformly along the peripheral portion of the bevel shadow ring 113. It should be noted that the number of spacers 115 is given as an example and should not be considered limiting.

A first end of each of the plurality of spacers 115 is received in a corresponding housing 115a defined in the bevel shadow ring 113. In some implementation, the housing 115a is defined to extend from a top surface to a depth or to a portion of the depth of the bevel shadow ring 113. A second end of each of the plurality of spacers 115 is received in a corresponding spacer housing 115b defined in the flow optimizer 120. In some implementation, the spacer housing 115b is defined to extend from a bottom surface to a depth or a portion of the depth of the flow optimizer 120. The spacer 115 may be a support pin although other types of spacer 115 may also be envisioned. The housing 115a for the spacer 115, in one implementation, is defined in the bevel shadow ring 113 so that the housing 115a of the spacer 115 aligns with the carrier ring 124. This alignment would allow the carrier ring 124 to provide support to not only the bevel shadow ring 113 but also to the flow optimizer 120 supported on the spacer 115 as the carrier ring 124 with the bevel shadow ring 113 is being moved vertically by a lift pin mechanism.

In one implementation, the lift pin mechanism connected to a plurality of lift pins 126 is defined in the wafer support 106a. In this implementation, the carrier ring 124 with the bevel shadow ring 113 received thereon is supported on the wafer support 106a. The lift pins 126 are distributed uniformly along a circumference of the wafer support 106a and are received in corresponding housing defined in the wafer support 106a. The lift pin mechanism is coupled to a controller (not shown). Control signals from the controller are used to operate the lift pin mechanism to enable the lift pins 126 to be moved to a raised position, when the lift pin mechanism is engaged, or a rested position, when the lift pin mechanism is disengaged. When engaged, the lift pins 126 are configured to extend out of the corresponding housing in the wafer support 106a and lift the carrier ring 124 and the bevel shadow ring 113 that is disposed on the carrier ring 124.

In some implementations, the number of spacers 115 defined between the flow optimizer 120 and the bevel shadow ring 113 corresponds with the number of lift pins 126 of the lift pin mechanism disposed in the wafer support 106a. The lift pins are disposed in the wafer support 106a so that it aligns with the carrier ring 124. In addition to aligning with the carrier ring 124, in some implementations, each lift pin 126 may substantially align with a corresponding spacer 115. FIG. 3B illustrates one such implementation. In another implementation, the number of lift pins 126 may be greater than or less than the number of spacers 115 distributed in the chamber 100. In this implementation, the lift pins 126 may or may not align with the spacers 115 but are configured to lift the carrier ring 124, the bevel shadow ring 113 and the flow optimizer 120, when the lift pins 126 are engaged.

In one implementation, the flow optimizer 120 is disposed below the dielectric window 102 at a distance that is defined to be between about 1.5″ and about 2.5″. The bevel shadow ring 113 is disposed below the dielectric window 102 at a distance that is defined to be between about 2.5″ and 3.5″. The plurality of spacers 115 separating the flow optimizer 120 from the bevel shadow ring 113 extends for a height that is defined to be about 1″. The outer diameter of the ring of the flow optimizer 120 is defined to be substantially equal to the inner diameter of the side walls of the chamber 100. In one implementation, if the inner diameter of the side walls of the chamber 100 is about 14″, the outer diameter of the annular surface of the ring is defined to be between about 13.5″ and about 13.99″. The width of the outer diameter of ring is shown to be less than the inner diameter of the side walls of the chamber so as to provide sufficient tolerance for the annular ring expansion. The aforementioned dimensions are provided as examples and should not be considered limiting. The distances between the flow optimizer 120 and the dielectric window 102, between the bevel shadow ring 113 and the dielectric window 102, between the flow optimizer 120 and the bevel shadow ring 113 or between the flow optimizer 120 and the wafer support 106a, and the width of the flow optimizer 120 may depend on the interior profile of the chamber 100. Similarly, the width of the bevel shadow ring 113 may depend on the amount of bevel edge of the wafer that needs to be covered to prevent exposure to the reactant species.

In one implementation, the lift pin mechanism may be engaged to move the bevel shadow ring 113 and the flow optimizer 120 out of the way when a wafer 110 needs to be moved into or out of the chamber 100. The wafer 110 may be moved into and out of the chamber 100 using a robot of a vacuum transfer module or any other module to which the chamber 100 is coupled within a substrate processing system, and the bevel shadow ring 113 and the flow optimizer 120 are moved to a height to allow an arm of the robot with the wafer to move into and out of the chamber 100 unhindered. The side walls of chamber 100 and the chamber wedge 130 defined in a portion of the side walls ensure that there is sufficient space for moving the flow optimizer 120 and the bevel shadow ring 113 vertically inside the chamber 100, when lifted by the lift pins. The height to which the flow optimizer 120 and the bevel shadow ring 113 can be moved by the lift pins 126 depends on the amount of space available in the chamber 100. In some implementations, the height of the spacers 115 defined between the flow optimizer 120 and the bevel shadow ring 113 may be equal to the height to which the carrier ring 124 with the bevel shadow ring 113 can be moved to be at a raised position.

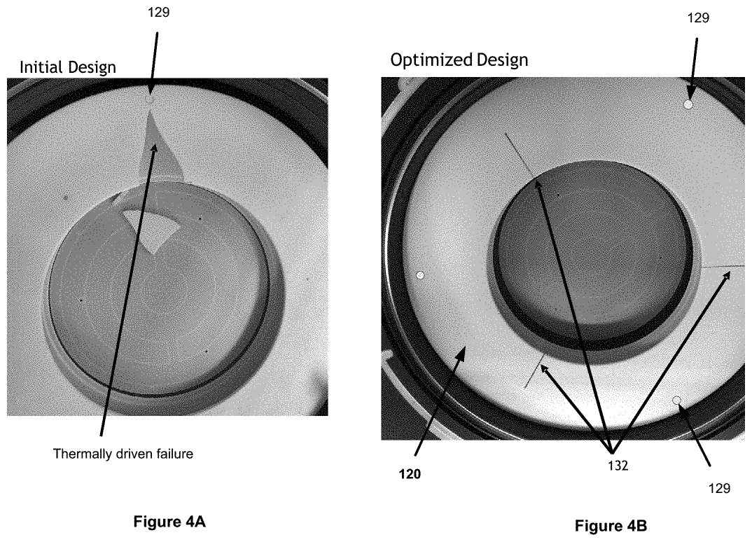

FIGS. 4A and 4B illustrate a top view of a flow optimizer 120 disposed inside the chamber 100 below the dielectric window 102. In some implementations, the flow optimizer 120 is made of ceramic due to its high etch resistance. However, due to its placement in the plasma region and its constant exposure to the plasma, the flow optimizer 120 experiences high thermal gradients, as a result of which it experiences high thermal stress. The thermal stress causes the flow optimizer 120 to experience some damage, such as breakage, cracks, etc., especially near weak spots, such as the outer edges. The weak spots at the outer edges may be due to the way the flow optimizer 120 is designed or due to presence of one or more connectors that connect the flow optimizer 120 to parts of the chamber 100. For instance, the flow optimizer 120 may be connected to the support pegs 128 through connector means (e.g., screws). FIG. 4A illustrates an instance where a part of the flow optimizer 120 near a connector means 129 (i.e., weak spot) has chipped away. To address the stress issue and to mitigate the damage to the flow optimizer 120, one or more stress relief cuts 132 may be introduced in the annular surface of the ring of the flow optimizer 120 exposed to the plasma. FIG. 4B illustrates a set of stress relief cuts 132 defined in the flow optimizer 120. The stress relief cuts 132 may be defined on the top surface of the flow optimizer 120 or in the body of the flow optimizer 120 and extend from the inner diameter of the annular surface (i.e., inner edge of the annular ring) to a distance that is less than the outer diameter of the flow optimizer 120 (i.e., outer edge of the annular ring). In the implementation illustrated in FIG. 4B, a set of 3 stress relief cuts 132 are defined uniformly along the circumference of the inner diameter of the annular ring. In some implementations, each of the stress relief cuts 132 is disposed at a distance from a corresponding weak spot identified in the flow optimizer 120. The location of the stress relief cuts 132 are not restricted to what is shown in FIG. 4B and that other locations on the top surface of the flow optimizer 120 for defining the stress relief cuts 132 may also be contemplated. These stress relief cuts 132 assist in reducing the thermal stress experienced by the flow optimizer 120.

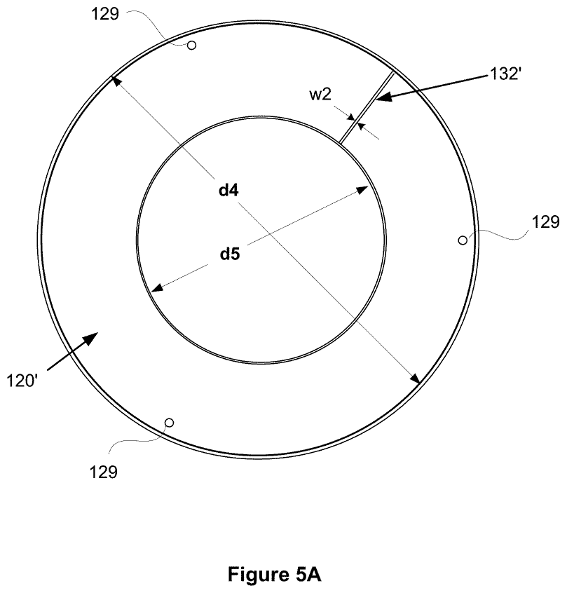

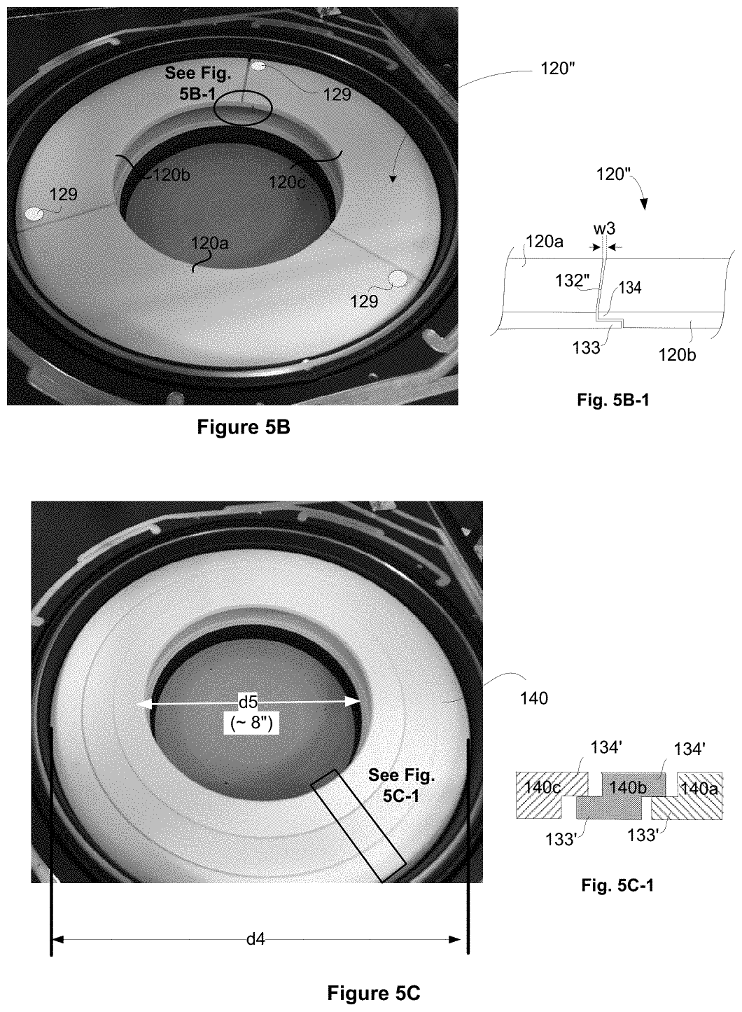

FIG. 5A illustrates an alternate implementation of stress relief cut 132′ defined on a flow optimizer 120′. In this implementation, only one stress relief cut 132′ is defined in the flow optimizer 120′, instead of a plurality of stress relief cuts 132 illustrated in FIG. 4B. The flow optimizer 120′ illustrated in FIG. 5A is also a ring-shaped structure with an outer edge of the annular ring extending to an outer diameter ‘d4’ and an inner edge defining the opening extends an inner diameter ‘d5’. The dimensions of the inner and the outer diameters of the annular ring of the flow optimizer 120 depend on the inner dimensions of the chamber 100 in which the flow optimizer 120 is disposed. In one implementation, in a chamber 100 wherein the inner diameter of the side walls extend to about 14″, the outer diameter d4 of the flow optimizer 120′ is defined to be between about 13.5″ and about 13.99″, and the inner diameter d5 is defined to be between about 7.5″ and about 8.5″. The outer diameter d4 of the flow optimizer 120′ is defined so as to include a gap between the outer diameter d4 and the side walls 112 of the chamber 100. The gap is defined to be sufficiently small to provide some tolerance for expansion. It should be noted that the aforementioned dimensions are given as an example and should not be considered restrictive. Other dimensions for the flow optimizer 120′ may also be envisioned so long as the functionality of the flow optimizer 120 (i.e., funneling the reactant species of the plasma toward the wafer) is maintained and the dimensions of the inside of the chamber 100 are taken into consideration when defining the flow optimizer 120′. A set of weak spots are shown on the top surface of the flow optimizer 120′ in FIG. 5A. The weak spots may be due to presence of connector means 129 (outline shown in FIG. 5A) used to connect the flow optimizer 120 to the support pegs 128 defined in the side walls 112 of the chamber 100.

The stress relief cut 132′ is defined in the body of the flow optimizer 120′ and extends from the inner edge to the outer edge of the flow optimizer 120′. The stress relief cut 132′, in this implementation, defines a separation cut as it extends the entire body of the ring of the flow optimizer 120′ for a width ‘w2’. The outer edge corresponds to the outer diameter d4 and the inner edge corresponds to the inner diameter d5 of the ring (also referred to as “annular ring”) of the flow optimizer 120. In one example implementation, the width w2 of the stress relief cut 132′ is defined to be between about 0.5 mm and about 2 mm.

FIG. 5B illustrates an alternate design of a flow optimizer 120. In this implementation, the flow optimizer 120″ is made of a plurality of segments. Each segment of the plurality of segments is defined to have an edge contour that complements an edge contour of a corresponding adjacent segment to define a “stress relief interface” 132′. For example, the flow optimizer 120″ illustrated in FIG. 5B is shown to include three segments (120a-120c). A lip 133 is defined at a first end along a bottom surface (i.e., lower side) of each segment of the flow optimizer 120″ and a complementary extension 134 is defined at a second end along a top surface (i.e., upper side). When the segments are aligned, the lip 133 on the first end of a first segment 120a mates with a complementary extension 134 from a second end of a second segment 120b, that is adjacent to first segment, 120a. Similarly, a lip 133 at the first end of the second segment 120b mates with a corresponding complementary extension 134 defined at the second end of a third segment 120c. FIG. 5B-1 illustrates an expanded view of the mating of two adjacent segments (segments 1 and 2) of the flow optimizer 120″ to define the stress relief cut 132″. The separation width between the lip 133 of a first segment and the complementary extension 134 of a second segment at the mating interface defining the stress relief cut 132″ is represented as ‘w3’. In one example implementation, the width w3 of the stress relief cut 132″ is defined to be between about 0.5 mm and about 1.5 mm. The dimension of the stress relief cut 132″ is provided as an example and should not be considered limiting. It should be noted that the dimension of the stress relief cut 132″ defined at the mating junction of the lip 133 and the complementary extension 134 of adjacent segments is suitably defined to enable the flow optimizer 120″ to withstand the thermal stress due to its constant exposure to the plasma in the plasma region 104.

In one implementation, connector means 129, outline of which is shown on the top surface of the flow optimizer 120″ in FIG. 5B, may be defined to pass through a portion of the lip 133 of each segment and a portion of a corresponding complementary extension 134 of an adjacent segment. This design may be to reinforce the weak section of each segment, which may be due to depth of the lip 133 and the extension 134 of each segment making the weak spot even more vulnerable to damage. In alternate implementation, the connector means 129 may be defined on the surface of the flow optimizer 120 away from the stress relief cut 132″, so as to avoid undue stress exertion at the weak sections of the each segment.

FIG. 5C illustrates another alternate design of a flow optimizer 140 that can be used in the chamber 100 to funnel the reactant species of the plasma toward the wafer surface, in one implementation. In this implementation, the flow optimizer 140 is defined by a plurality of concentric, nested rings. FIG. 5C-1 shows an expanded cross-sectional view of a portion of the flow optimizer 140 showing the plurality of concentric, nested rings. As shown in FIG. 5C-1, the flow optimizer 140 is shown to have a set of 3 concentric, nested rings, 140a through 140c. The first ring 140a is configured to include a lip 133′ at a bottom surface of an inner edge. An outer edge of the first ring 140a lines the outer diameter of the flow optimizer 140. The bottom surface and the top surface of the first ring 140a are designed to be planar. A step is defined from an inner edge of the top surface to an inside edge of the lip 133′. A second ring 140b adjacent to the first ring 140a includes a lip 133′ defined at a bottom surface of an inner edge and an extension 134′ defined at a top surface of an outer edge. The contour of the extension 134′ at the outer edge of the second ring 140b complements the contour of the lip at the inner edge of the first ring 140a. A third ring 140c includes an extension 134′ on a top surface of the outer edge and a planar surface along a bottom surface of an inner edge. A side edge defined between the inner edge of the top surface and inner edge of the bottom surface of the third ring 140c defines the inner edge of the flow optimizer 140. The contour of the extension 134′ of the third ring 140c complements the contour of the lip 133′ of the adjacent second ring 140b. The design of the first, second and third rings illustrated in FIG. 5C define a nested ring structure of the flow optimizer 140. As in the previous implementations, the inner diameter d5 of the flow optimizer 140 is defined to be between about 7.5″ and about 8.5″ and the outer diameter d4 of the flow optimizer 140 is defined to be between about 13.5″ and about 13.99″. It should be noted that the aforementioned dimensions are provided as examples and the dimensions of the flow optimizer 140 may vary depending on the inner dimensions of the chamber 100 in which the flow optimizer 140 is received.

In some implementations, when the extension 134′ of the second ring 140b is received on the lip 133′ of the first ring 140a, a first gap may be present at a corresponding interface defined between the extension 134′ of the second ring 140b and the lip 133′ of the first ring 140a. Similarly, when the extension 134′ of the third ring 140c is received over the lip 133′ of the second ring 140b, a second gap may be present at the corresponding interface defined between the extension 134′ of the third ring 140c and the lip 133′ of the second ring 140b. These gaps may be designed to perform the functions of a stress relief cut (i.e., provide space for expansion). As a result, no additional stress relief cuts are defined on the surface of the flow optimizer 140. In alternate implementations, one or more stress relief cuts may be defined in each of the concentric, nested rings 140a through 140c of the flow optimizer 140 to ensure that there is sufficient space for thermal expansion for the different rings (140a-140c) of the flow optimizer 140. The amount of space may be, in one implementation, based on coefficient of thermal expansion of the material used for the rings.

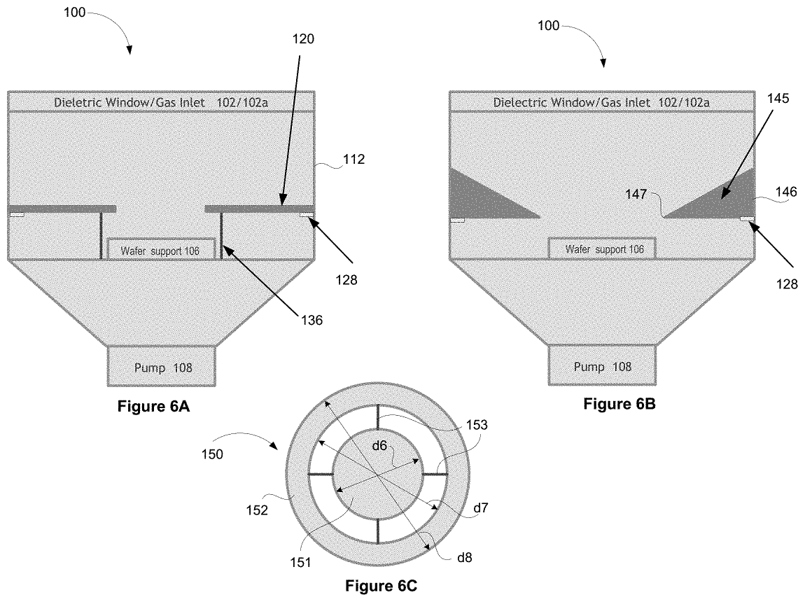

FIGS. 6A-6C illustrate variations in the design of the flow optimizer and inclusion of a plasma confinement structure in the chamber 100, in different implementations. FIG. 6A shows one variation in which the flow optimizer 120 is shown to be a planar, ring-shaped structure defined below the plasma region 104 of the chamber 100. The flow optimizer is supported by a plurality of support pegs 128 defined in the side walls 112 of the chamber 100. The size of the flow optimizer 120 may be defined so that the diameter of the opening in the flow optimizer 120 is less than the diameter of the wafer support 106a. As a result, a portion of the flow optimizer 120 overhangs over a portion of the edge of the wafer support 106a. When a wafer 110 is received on the wafer support 106a, the overhang of the flow optimizer 120 may cover a portion of the edge of the wafer 110. A plasma confining liner 136 is defined in the chamber 100 so as to confine the plasma within the plasma region 104 and to enable the reactant species to interact with the surface of the wafer 110. In one implementation, the plasma confining liner 136 may be made of anodized aluminum. The plasma confining liner 136 is disposed such that a top end of the plasma confining liner 136 is disposed at an underside surface of the ring of the flow optimizer 120 and a bottom end of the plasma confining liner 136 is disposed at the bottom of the chamber 100 proximal to the bottom surface of the wafer support 106a. The plasma confining liner 136 is disposed proximal to the opening of the flow optimizer 120. The plasma confining liner 136 is a ring-shaped structure with a vertical wall that extends down from the bottom surface of the flow optimizer 120 to the bottom surface of the wafer support 106a. The diameter of the plasma confining liner 136 is defined to be greater than the inner diameter of the ring of the flow optimizer 120 and the wafer support 106a, so as to allow the plasma confining liner 136 to sufficiently surround the wafer support 106a and define a gap between walls of the wafer support 106a and the plasma confining liner 136. The gap is defined to provide an unhindered path for the reactant species to flow toward the pump 108. The plasma confining liner 136 may be defined in the chamber 100 to increase the resident time for the reactant species on the wafer surface to allow the reactant species to interact with the wafer surface.

A plurality of support pegs 128 is disposed on the side walls 112 of the chamber 100 to provide support to the flow optimizer 120. The support pegs 128 are defined at a height from the wafer support 106a, and the height is defined so as to allow vertical movement of a wafer received on the wafer support 106a or received on a carrier ring that is received on the wafer support 106a. In some implementations, the height at which the support pegs 128 are defined ensures unhindered movement of the wafer into and out of the chamber 100.

FIG. 6B illustrates an alternate design of the flow optimizer received in the chamber 100 to force the reactant species of the plasma toward the wafer surface, in one implementation. The annular surface of the ring of the flow optimizer 145 is designed to be in the shape of a wedge. In some implementations, the wedge-shaped ring of the flow optimizer 145 may be made of anodized aluminum. In alternate implementations, the wedge-shaped flow optimizer 145 may be made of ceramic. A broad side 146 of the wedge-shaped flow optimizer 145 is disposed proximate (e.g., adjacent) to the side walls 112 of the chamber 100 while the narrow side 147 of the wedge-shaped flow optimizer 145 is disposed on the side where the opening is formed. As with the implementation illustrated in FIG. 6A, the flow optimizer 145 of FIG. 6B is supported on a plurality of support pegs 128 defined on the side walls 112 of the chamber 100. The flow optimizer 145 is annular in structure. The shape of the wedge increases the etch rate at the wafer edge by enabling the reactant species to flow down toward the wafer and recycle. In some implementation, the recycling of the reactant species may result in swirls (similar to ‘eddy’ swirls). In some implementations, the the flow optimizer 120 may be coated with Yttria (i.e., yttrium oxide) to protect the surface of the flow optimizer 120 from the chemistry used in the chamber 100.

FIG. 6C illustrates another design implementation of a flow optimizer 150 used in the chamber 100. In this example, the flow optimizer 150 is a multi-ring flow optimizer with an inner disk 151, an outer ring 152 disposed concentric to the inner disk 151 to define a gap located therebetween. The inner disk 151 includes a surface that extends for a diameter ‘d6’. Diameter d6 of the inner disk 151 may be defined to cover a portion of the surface of the wafer 110 received on the wafer support 106a. In some implementations, the diameter d6 of the inner disk 151 may be defined to expose an edge region of the wafer 110 received on the wafer support 106a to the reactant species of the plasma and block the remaining portion of the wafer 110 from getting exposed to the reactant species. This design of the flow optimizer 150 may be contemplated when the etch rate has be increased at the wafer edge instead of the wafer center. In alternate implementation, the diameter d6 of the inner disk 151 may be defined based on specific portion of the wafer surface that needs to be exposed to the reactant species. Thus, the diameter d6 of the inner disk 151 may depend on the size of the wafer 110, and an amount of the surface of the wafer 110 or the amount of the edge of the wafer 110 that needs to be exposed to the reactant species of the plasma. The outer ring 152 includes an annular surface that extends from an inner edge defined by an inner diameter ‘d7’ to an outer edge defined by an outer diameter ‘d8’. The outer diameter d8 of the outer ring 152 may be defined so that the outer edge is disposed adjacent to the side walls 112 of the chamber 100. The inner diameter d7 of the outer ring 152, a size of the gap, width of the annular surface of the outer ring 152, and the size of the inner disk 151 are defined based on which portion of the wafer surface and how much of the wafer surface needs to be exposed to the reactant species. The inner disk 151 may be a replaceable part that can be carried in and out of the chamber 100 using a carrier ring 124, which may be similar to the one that may be used for transporting the wafer 110 while the outer ring 152 may be attached to a plurality of support pegs 128 (not shown) defined on the side walls 112 of the chamber 100.

A plurality of connector pins 153 is disposed to connect the inner disk 151 to the outer ring 152. In one implementation, a set of four connector pins 153 are disposed uniformly along the outer edge of the inner disk 151. It should be noted that the number of connector pins 153 are given as an example and should not be considered restrictive. Fewer or greater than four connector pins 153 may be used to connect the inner disk 151 to the outer ring 152.

The various implementations discussed herein disclose different designs of a flow optimizer that may be disposed in a chamber 100 to direct a greater amount of reactant species to pass close to the wafer surface so they can react with the wafer surface. In the implementations that include a ring-shaped flow optimizer, the ring-shaped flow optimizer may be aligned with the diameter of the wafer support 106a so that the opening may be centered over the wafer to allow the reactant species to be funneled over the wafer surface. The size of the opening and the size of the annular surface of the ring may be defined to cause an increased amount of the reactant species to be applied to specific portions of the wafer surface exposed to the reactant species. The increase in the amount of reactant species applied to the wafer surface results in an improvement in the etch rate and this improvement is realized without increasing amount of process gas or the power applied to the inside the chamber 100. The flow optimizer may be made of high etch resistant material, such as ceramic, etc., or materials with lower coefficient of thermal expansion, such as quartz, etc., or materials with higher thermal conductivity or lower brittleness, such as anodized aluminum, etc.

A comparison of profile of features etched on the surface of a wafer in the chamber 100 without the flow optimizer 120 and in the chamber 100 with the flow optimizer 120 appear to be same, indicating that the trench profiles were not adversely affected by the introduction of the flow optimizer in the chamber 100. Further, the etch rate at different radii of the wafer surface starting from the wafer center to the wafer edge when the wafer was etched inside a chamber 100 that was equipped with a flow optimizer 120 showed a significant improvement (e.g., about 25% improvement) than when no flow optimizer 120 was used in the chamber 100. The significant increase may be attributed to having more of the reactant species distributed on the wafer surface.

The improvement in the etch rate and uniformity of etching across the surface of the wafer is realized without any tradeoffs resulting from increasing reactant species in the chamber, wherein the increase in the reactant species was done by increasing power applied to generate the plasma or process gas flow. The tradeoffs that came with increasing gas flow or power resulted in degraded profiles and less than optimal etch uniformity. On the other hand, the etch rate improvement in the presence of the flow optimizer and the profile uniformity was fairly steady across the different regions of the wafer surface. The flow optimizer enables efficient use of the reactant species that is already present in the chamber and the increase in the reactant species comes without a need to expend additional power or increase gas flow to the chamber. Other advantages of the various implementations will be understood by those skilled in the art.

With the above embodiments in mind, it should be understood that some of the embodiments employ various computer-implemented operations involving data stored in computer systems to perform the etching operation within the chamber. The chamber may be connected to a controller, which may be part of a computer system or may communicate with a computer system to control the etching operation in the chamber. The etching operation is that which physically manipulates physical quantities, such as process recipes that influence generation of plasma for the etching operations. Any of the operations described herein that form part of the embodiments are useful machine operations. The computer system may be a special purpose computer. When defined as a special purpose computer, the computer performs other processing, program execution or routines that are not part of the special purpose, while still being capable of operating for the special purpose.

In some embodiments, the operations may be processed by a computer selectively activated or configured by one or more computer programs stored in a computer memory, cache, or obtained over the computer network. When data is obtained over the computer network, the data may be processed by other computers on the computer network, e.g., a cloud of computing resources.

One or more embodiments can include operations that can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

It should further be noted that in an embodiment, one or more features from any embodiment described above are combined with one or more features of any other embodiment without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A flow optimizer for use in a plasma chamber having side walls, a wafer support and a dielectric window disposed opposite to the wafer support to define a plasma region located therebetween, a gas inlet is provided through the dielectric window for directing gas to the plasma region, the flow optimizer comprising:
a ring having an annular surface with an inner edge that extends an inner diameter and an outer edge that extends to an outer diameter, the ring is disposed such that the outer edge of the ring is adjacent to the side walls of the plasma chamber and the inner diameter defines an opening,
wherein the ring of the flow optimizer is configured to be positioned between the wafer support and the dielectric window so that the opening of the ring is substantially aligned with a diameter of the wafer support.

2. The flow optimizer of claim 1, wherein the ring is disposed above the wafer support, such that a separation distance exists between the ring and the wafer support.

3. The flow optimizer of claim 2, wherein the ring of the flow optimizer is supported on a plurality of support pegs defined on an inner side of the side walls of the plasma chamber, a height of the support pegs is defined by the separation distance.

4. The flow optimizer of claim 2, wherein the ring of the flow optimizer is supported on a plurality of spacers defined on a top surface of the wafer support so as to define a gap between the flow optimizer and the wafer support, a size of the gap is defined by the separation distance.

5. The flow optimizer of claim 2, wherein the separation distance is defined to be between about 0.5″ and about 1.5″.

6. The flow optimizer of claim 1, wherein the wafer support is configured to receive a carrier ring used for moving a wafer into and out of the plasma chamber.

7. The flow optimizer of claim 1, wherein the inner diameter of the opening is less than, equal to, or greater than a diameter of the wafer support.

8. The flow optimizer of claim 1, wherein the flow optimizer dissects plasma in the plasma region into an upper plasma region and a lower plasma region, the upper plasma region connected to the lower plasma region at the opening of the ring, and
wherein a flow of reactant species of the plasma from the upper plasma region to the lower plasma region is restricted by the annular surface of the ring to cause the reactant species to flow toward the wafer support.

9. The flow optimizer of claim 1, wherein the ring of the flow optimizer is a wedge shaped annular ring, a broad side of the wedge shaped annular ring is disposed adjacent to the side walls of the plasma chamber and a narrow side of the wedge shaped annular ring is disposed adjacent to the opening.

10. The flow optimizer of claim 1, wherein the flow optimizer includes one or more stress relief cuts that extend from the inner diameter to the outer diameter of the ring.

11. The flow optimizer of claim 1, wherein the ring of the flow optimizer includes a plurality of segments, wherein each segment of the plurality of segments includes a lip defined at a first end along a lower side and a complementary extension defined at a second end along an upper side, such that the lip of a first segment is configured to mate with the complementary extension of a second segment.

12. A plasma chamber having side walls, a wafer support and a dielectric window disposed opposite to the wafer support to define a plasma region located therebetween, a gas inlet is provided through the dielectric window for directing gas to the plasma region, the plasma chamber comprising:
a flow optimizer having a ring with an annular surface, the annular surface defined by an inner edge that extends an inner diameter and an outer edge that extends to an outer diameter, the ring is disposed such that the outer edge of the ring is adjacent to the side walls of the plasma chamber and the inner diameter defines an opening,
wherein the ring is configured to be positioned between the wafer support and the dielectric window so that the opening of the ring is substantially aligned with a diameter of the wafer support; and
wherein the flow optimizer is supported on a plurality of support pegs defined on an inner side of the side walls of the plasma chamber, the plurality of support pegs are disposed above the wafer support so that a separation distance exists between the wafer support and the ring of the flow optimizer.

13. The plasma chamber of claim 12, further includes a plurality of lift pins distributed uniformly along the wafer support so as to align with a carrier ring used for moving a wafer into and out of the plasma chamber, the plurality of lift pins configured to support and move the carrier ring with the wafer between a raised position and a rested position, wherein the wafer support has a housing to receive corresponding lift pin of the plurality of lift pins, the plurality of lift pins connected to a lift pin mechanism that is coupled to a controller, signals from the controller configured to control movement of the plurality of lift pins.

14. The plasma chamber of claim 12, further includes a bevel shadow ring disposed between the flow optimizer and the wafer support.

15. The plasma chamber of claim 14, wherein the bevel shadow ring is separated from the dielectric window by a first height, and the flow optimizer is separated from the dielectric window by a second height, such that the flow optimizer is above the wafer support and below the plasma region defined in the plasma chamber and the bevel shadow ring is above the wafer support and below the flow optimizer.

16. The plasma chamber of claim 15, wherein the first height is defined to be between about 1.5″ and about 2.5″, and
wherein the second height is defined to be between about 2.5″ and about 3.5″.

17. The plasma chamber of claim 12, further includes a plasma confining liner disposed to surround the wafer support, the plasma confining liner configured to extend downward from an underside surface of the ring up to a bottom surface of the wafer support, so that a gap exists between the plasma confining liner and walls of the wafer support for plasma to escape.

18. The flow optimizer of claim 17, wherein a diameter of the plasma confining liner is greater than the inner diameter of the ring and a diameter of the wafer support.

19. A flow optimizer for use in a plasma chamber having side walls, a wafer support and a dielectric window disposed opposite to the wafer support to define a plasma region located therebetween, a gas inlet is provided through the dielectric window for directing gas to the plasma region, the flow optimizer comprising:
an inner disk defined in a center and aligned with a diameter of the wafer support, an outer edge of the inner disk extends to a first diameter;
an outer ring having an annular surface with an inner edge of the outer ring extending to a second diameter and an outer edge of the outer ring extending to a third diameter, the inner edge of the outer ring is separated from the outer edge of the inner disk by a gap defined to expose a portion of a wafer received on the wafer support; and
a plurality of connector pins disposed to connect the outer edge of the inner disk and the inner edge of the outer ring,
wherein the flow optimizer is configured to be positioned between the wafer support and the dielectric window.

20. The flow optimizer of claim 19, wherein the first diameter of the inner disk is less than the second diameter of the outer ring, and
wherein a size of the gap is defined based on the portion of the wafer and an amount of the portion of the wafer that is to be exposed for etching.

21. The flow optimizer of claim 19, wherein the first diameter of the inner disk, the second diameter of the outer ring, a width of the annular surface of the outer ring and a size of the gap are defined based on the portion of the wafer and an amount of the portion of the wafer that is to be exposed for etching.

22. The flow optimizer of claim 21, wherein the flow optimizer is disposed above the wafer support, such that a separation distance exists between the flow optimizer and the wafer support.

23. The flow optimizer of claim 22, wherein the separation distance is defined to be between about 0.5″ and about 1.5″.

24. The flow optimizer of claim 19, wherein the flow optimizer is made of ceramic material.
